(19) United States
(12) Patent Application Publication
(10) Pub. No.: US 2025/0268047 A1
(43) Pub. Date: Aug. 21, 2025

(54) DISPLAY DEVICE

(71) Applicant: LG Display Co., Ltd., Seoul (KR)

(72) Inventor: Sungman HAN, Paju-si (KR)

(21) Appl. No.: 18/951,153

(22) Filed: Nov. 18, 2024

(30) Foreign Application Priority Data
Feb. 15, 2024 (KR) 10-2024-0021500

(51) Int. Cl. H10K 59/32; H10K 59/35; H10K 59/80

(52) U.S. Cl. CPC H10K 59/32; H10K 59/351; H10K 59/805

(57) ABSTRACT

Embodiments of the present disclosure relates to a display device. The display device includes an auxiliary electrode disposed between the emission areas of adjacent subpixels among the plurality of subpixels and disposed on the overcoat layer. The display device includes an organic layer disposed on the overcoat layer and the auxiliary electrode. The organic layer including at least one charge generation layer. At least a portion of the at least one charge generation layer is in contact with the auxiliary electrode, thereby improving the color gamut of the display device by blocking leakage current flowing between adjacent subpixels.

### CROSS REFERENCE TO RELATED APPLICATION

This application claims priority from Korean Patent Application No. 10-2024-0021500, filed on Feb. 15, 2024, which is hereby incorporated by reference for all purposes as if fully set forth herein.

### BACKGROUND

### Technical Field

The present disclosure relates to a display device.

### Description of the Related Art

As technology advances, a display device for displaying image is becoming more integrated and thinner.

A display device may include a display panel including various elements, transistors, etc., to display images. The display panel may include a plurality of subpixels which implement different colors to display an image.

In this case, as display devices become more integrated, multiple subpixels may be arranged more densely, so the gap between adjacent subpixels may narrow.

### BRIEF SUMMARY

If the gap between adjacent subpixels in the display device of the related art becomes narrow, interference may occur between subpixels, making it difficult to independently control the light emission of the subpixels. This may also deteriorate the color gamut characteristics of the display device. Various embodiments of the present disclosure address the technical problems in the related art, including the problem identified above.

Embodiments of the present disclosure may provide a display device capable of improving the color gamut by blocking leakage current flowing between adjacent subpixels.

Embodiments of the present disclosure may provide a display device including a substrate including a plurality of subpixels, each of the plurality of subpixels including an emission area, an overcoat layer on the substrate, an auxiliary electrode disposed between the emission areas of adjacent subpixels among the plurality of subpixels and disposed on the overcoat layer, and an organic layer disposed on the overcoat layer and the auxiliary electrode, including at least one charge generation layer, and at least a portion of the at least one charge generation layer contacting the auxiliary electrode.

Embodiments of the present disclosure may provide a display device including a substrate including a plurality of subpixels, each of the plurality of subpixels including an emission area, an overcoat layer on the substrate, an auxiliary electrode disposed between emission areas of adjacent subpixels among the plurality of subpixels and disposed on the overcoat layer, and an organic layer disposed on the overcoat layer and the auxiliary electrode, at least a portion of the organic layer contacting a side surface of the auxiliary electrode.

According to embodiments of the present disclosure, there may provide a display device capable of improving the color gamut by blocking leakage current flowing between adjacent subpixels.

According to embodiments of the present disclosure, there may provide a display device capable of blocking leakage current flowing between adjacent subpixels, thereby enabling low power consumption by preventing unnecessary power consumption.

### BRIEF DESCRIPTION OF THE SEVERAL VIEWS OF THE DRAWINGS

FIG. 1 illustrates an example of the structure of a display device and a circuit structure included in a subpixel according to embodiments of the present disclosure.

FIG. 2 illustrates an example of a planar structure of a subpixel.

FIG. 3 illustrates an example of the cross-sectional structure of portion I-I′ of FIG. 2.

FIG. 4 illustrates an example of the organic layer shown in FIG. 3.

FIG. 5 is an enlarged view of part A of FIG. 3.

FIG. 6 illustrates another example of the cross-sectional structure shown in FIG. 5.

FIG. 7 is a table illustrating the color gamut of a display device according to embodiments of the present disclosure.

FIG. 8 illustrates another example of the cross-sectional structure shown in FIG. 5.

FIG. 9 illustrates an example of a planar structure of a display panel according to embodiments of the present disclosure.

FIG. 10 illustrates an example of the cross-sectional structure of portion II-II′ of FIG. 9.

FIGS. 11 and 12 illustrate another example of a planar structure of a subpixel.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range (e.g., 10%) that may be caused by various factors (e.g., process factors, internal or external impact, noise, etc.) even when a relevant description is not specified. Further, the term “may” fully encompasses all the meanings of the term “can”.

Hereinafter, embodiments will be described in detail with reference to the accompanying drawings.

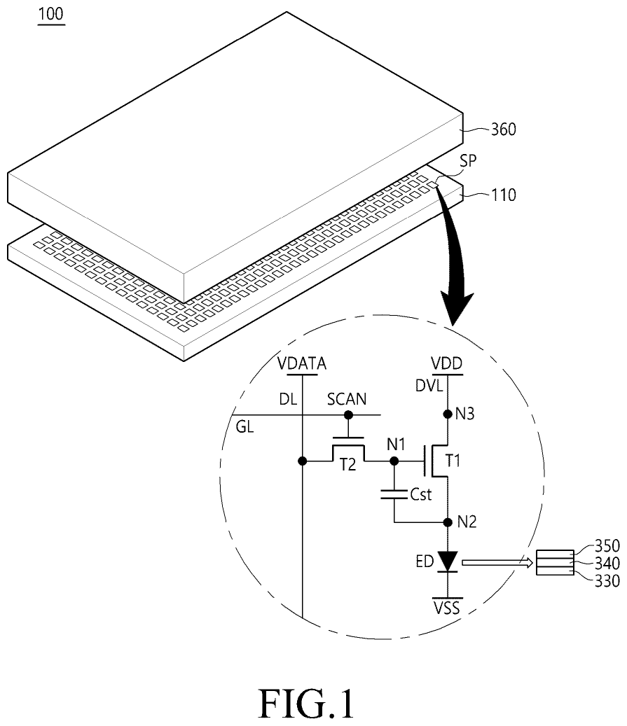

FIG. 1 illustrates an example of the structure of a display device and a circuit structure included in a subpixel according to embodiments of the present disclosure.

Referring to FIG. 1, a plurality of subpixels SP may be disposed in a display panel 110 included in a display device 100.

Each of the plurality of subpixels SP may include a light emitting device ED and a subpixel circuit unit configured to drive the light emitting device ED.

The subpixel circuit unit may include a driving transistor T1 for driving the light emitting device ED, a scan transistor T2 for transferring the data voltage VDATA to a first node N1 of the driving transistor T1, and a storage capacitor Cst for maintaining a constant voltage during one frame.

The driving transistor T1 may include a first node N1 to which a data voltage is applied, a second node N2 electrically connected to the light emitting device ED, and a third node N3 to which the driving voltage VDD is applied from a driving voltage line DVL. In the driving transistor T1, the first node N1 may be a gate node, the second node N2 may be a source node or a drain node, and the third node N3 may be a drain node or a source node. Hereinafter, for convenience of explanation, there illustrates a case in which the first node N1 is a gate node, the second node N2 is a source node, and the third node N3 is a drain node in the driving transistor T1, as an example.

The light emitting device ED may include an anode electrode 330, an organic layer 340, and a cathode electrode 350. The anode electrode 330 may be a pixel electrode disposed in each subpixel SP, and may be electrically connected to the second node N2 of the driving transistor T1 of each subpixel SP. The cathode electrode 350 may be a common electrode commonly disposed in the plurality of subpixels SP, and a base voltage VSS may be applied thereto.

Alternatively, the anode electrode 330 may be a common electrode, and the cathode electrode 350 may be a pixel electrode. Hereinafter, for convenience of explanation, it is assumed that anode electrode 330 is a pixel electrode and the cathode electrode 350 is a common electrode.

The light emitting device ED may have a specific emission area, and the emission area of the light emitting device ED may be defined as an area where the anode electrode 330, the organic layer 340, and the cathode electrode 350 overlap.

The light emitting device ED may be an organic light emitting diode (OLED), an inorganic light emitting diode, or a quantum dot light emitting device. In the case that the light emitting device ED is an organic light emitting diode, the organic layer 340 in the light emitting device ED may include an organic emission layer containing an organic material.

The scan transistor T2 may be controlled on-off by a scan signal SCAN, which is a gate signal applied through a gate line GL, and the scan transistor T2 may be electrically connected between the first node N1 of the driving transistor T1 and the data line DL.

The storage capacitor Cst may be electrically connected between the first node N1 and the second node N2 of the driving transistor T1.

The subpixel circuit unit may have a 2T1C structure including two transistors DT and ST and one capacitor Cst, and in some cases, may further include one or more transistors. Alternatively, the subpixel circuit unit may further include one or more capacitors.

The storage capacitor Cst may be an external capacitor intentionally designed outside the driving transistor T1 rather than a parasitic capacitor (e.g., Cgs, Cgd) which is an internal capacitor existing between the first node N1 and the second node N2 of the driving transistor T1. Each of the driving transistor T1 and the scan transistor T2 may be an n-type transistor or a p-type transistor.

Circuit elements within each subpixel, in particular, light emitting devices EDs implemented with organic light emitting diodes OLEDs containing organic materials may be vulnerable to external moisture or oxygen. Accordingly, an encapsulation layer 360 may be disposed on the display panel 110 to prevent oxygen from penetrating into the circuit elements (particularly, the light emitting devices ED). The encapsulation layer 360 may be disposed to cover the light emitting device ED.

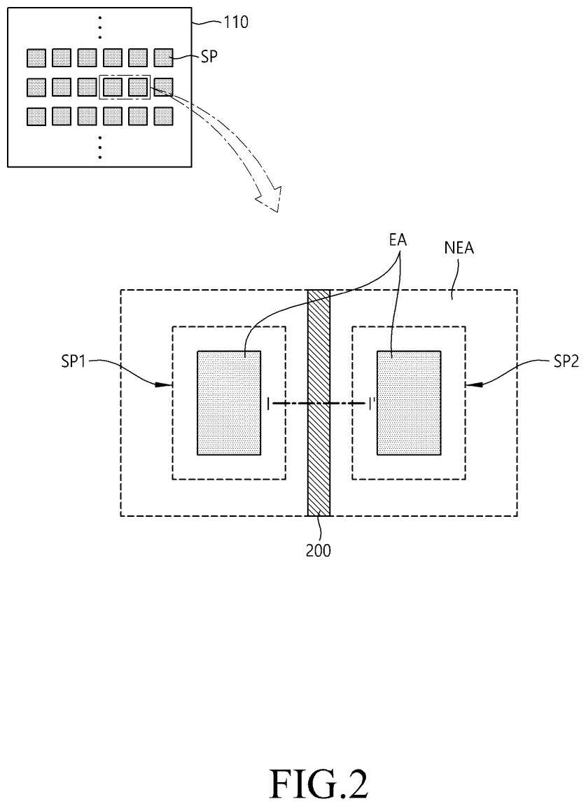

FIG. 2 illustrates an example of a planar structure of a subpixel.

Referring to FIG. 2, a display panel 110 may include a plurality of subpixels SP.

The plurality of subpixels SP may include a first subpixel SP1 and a second subpixel SP2.

The first subpixel SP1 and the second subpixel SP2 may be one of a red subpixel, a green subpixel, and a blue subpixel, respectively. Alternatively, the first subpixel SP1 and the second subpixel SP2 may be one of a red subpixel, a green subpixel, a blue subpixel, and a white subpixel, respectively, however is not limited thereto.

Each subpixel SP1 and SP2 may include a light emitting area or an emission area EA.

As described above, the emission area EA may be an area where an anode electrode, an organic layer, and a cathode electrode overlap.

Red, green, or blue light may be emitted from the emission area EA of the first subpixel SP1 and the second subpixel SP2. Alternatively, red, green, blue, or white light may be emitted.

A non-emission area NEA may be an area other than the emission area EA, and may refer to an area where the light is not emitted and is dark compared to the emission area EA.

The non-emission area NEA may surround the emission area EA. The area between the emission area EA of the first subpixel SP1 and the emission area EA of the second subpixel SP2 may be a non-emission area NEA. A circuit for driving a light emitting device may be disposed in the non-emission area NEA.

An auxiliary electrode 200 may be disposed in the non-emission area NEA between the emission areas EA of adjacent subpixels SP1 and SP2. Although not shown, the auxiliary electrode 200 may be disposed between anode electrodes included in adjacent subpixels SP1 and SP2, respectively.

The auxiliary electrode 200 may be made of a transparent conductive material capable of transmitting light. For example, the auxiliary electrode 200 may be formed of at least one of indium tin oxide (ITO) and indium zinc oxide (IZO), however, is not limited thereto.

The auxiliary electrode 200 may extend in a direction perpendicular to the direction extending from the first subpixel SP1 to the second subpixel SP2, and may extend to a non-display area where subpixels SPs are not disposed, however, is not limited thereto.

In FIG. 2, the auxiliary electrode 200 is shown to be disposed only between the first subpixel SP1 and the second subpixel SP2, but is not limited thereto, and the auxiliary electrode 200 may also be disposed between other adjacent subpixels.

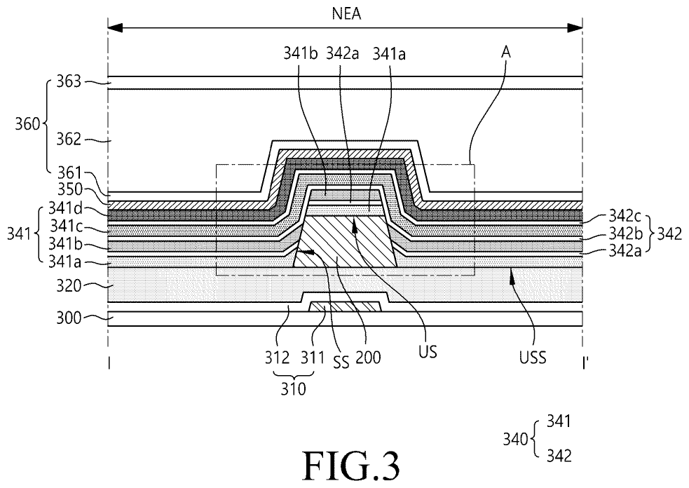

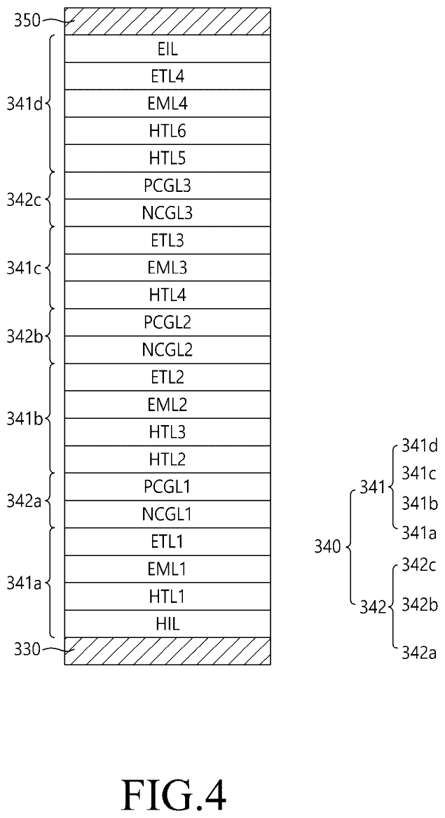

FIG. 3 illustrates an example of the cross-sectional structure of portion I-I′ of FIG. 2. FIG. 4 illustrates an example of the organic layer shown in FIG. 3.

Referring to FIG. 3, the display device may include a substrate 300 on which a plurality of subpixels SP are disposed.

The substrate 300 may support various components of the display device. The substrate 300 may be made of a flexible plastic material, but is not limited thereto.

A circuit element layer 310 may be disposed on the substrate 300.

The circuit element layer 310 may include various circuit elements for driving subpixels, such as a driving transistor, a sensing transistor, a storage capacitor, a line 311, and a buffer layer 312.

The line 311 may be disposed on the substrate 300, and may be a data line, a driving voltage line, or a sensing line.

The line 311 may be disposed in the non-emission area NEA.

A buffer layer 312 may be disposed on the substrate 300, and may be disposed to cover the line 311. The buffer layer 312 may prevent ions or impurities from diffusing from the substrate 300 and block moisture penetration. In addition, the buffer layer 312 may improve the surface flatness. The buffer layer 312 may include an inorganic material such as oxide or nitride, an organic material, or an organic-inorganic composite, and may be formed in a single-layer or multi-layer structure. For example, the buffer layer 312 may have a triple layer or more structure composed of silicon oxide, silicon nitride, and silicon oxide.

The circuit element layer 310 may include an active layer (not shown), a gate insulating layer (not shown), and a plurality of electrodes (not shown).

The active layer may be disposed on the buffer layer 312. The active layer may be formed of a silicon-based semiconductor material or an oxide-based semiconductor material. The active layer may include a source area, a drain area, and a channel area between the source area and the drain area.

The gate insulating layer may be disposed on the active layer.

A plurality of electrodes may be disposed on the gate insulating layer. The plurality of electrodes may include a gate electrode, a source electrode, and a drain electrode.

A color filter may be disposed on the buffer layer 312. The color filter may be disposed between the buffer layer 312 and an overcoat layer 320, and may be disposed to overlap the emission area EA of the subpixel SP.

The overcoat layer 320 may be disposed on the buffer layer 312.

The overcoat layer 320 may include an organic material such as polyimide, benzocyclobutene series resin, or acrylate, but is not limited thereto.

The overcoat layer 320 may prevent gas generated within the display device from being delivered to the light emitting device ED.

Although FIG. 3 exemplarily illustrates a case where the overcoat layer 320 is made of a single layer, the overcoat layer 320 is not limited thereto, and may be formed of a double layer or a triple layer.

On the overcoat layer 320, an anode electrode may be disposed in an area overlapping with an area where the subpixel SP is disposed.

In the case that the overcoat layer 320 is formed of a double layer, the overcoat layer 320 may include a first overcoat layer and a second overcoat layer. The second overcoat layer may be open in at least a portion of the first overcoat layer, and an anode electrode of the subpixel SP may be disposed on the second overcoat layer.

The anode electrode may be made of a transparent conductive material transmitting light. For example, the anode electrode may be formed of at least one of indium tin oxide (ITO) and indium zinc oxide (IZO). However, it is not limited thereto.

On the overcoat layer 320, an auxiliary electrode 200 may be disposed between the subpixels SP.

The auxiliary electrode 200 may be located in the non-emission area NEA.

A thickness of the auxiliary electrode 200 may be 800 Å or less, however, is not limited thereto.

The organic layer 340 may be disposed on the overcoat layer 320 and the auxiliary electrode 200.

The organic layer 340 may include a plurality of intermediate layers 341 and a plurality of charge generation layers 342. The organic layer 340 may be in the form of a plurality of intermediate layers 341 and a plurality of charge generation layers 342 alternately stacked.

Referring to FIG. 4, the organic layer 340 may be disposed between each anode electrode 330 and the cathode electrode 350 corresponding to the subpixel.

The plurality of intermediate layers 341 may include a first intermediate layer 341a, a second intermediate layer 341b on the first intermediate layer 341a, a third intermediate layer 341c on the second intermediate layer 341b, and a fourth intermediate layer 341d on the third intermediate layer 341c.

In FIGS. 3 and 4, the organic layer 340 is shown as having four intermediate layers 341, but it is not limited thereto, and the organic layer 340 may have two or three intermediate layers 341.

The plurality of charge generation layers 342 may include a first charge generation layer 342a, a second charge generation layer 342b on the first charge generation layer 342a, and a third charge generation layer 342c on second charge generation layer 342b.

In FIGS. 3 and 4, the organic layer 340 is shown as having three charge generation layers 342, but the organic layer 340 is not limited thereto, and may have one or two charge generation layers 342.

Specifically, the first intermediate layer 341a may be disposed on the anode electrode 330. The first intermediate layer 341a may have a structure in which a hole injection layer HIL, a first hole transport layer HTL1, and a first emission layer EML1 which emits light of a first color, a first electron transport layer ETL1 are sequentially stacked, but is not necessarily limited thereto. The first emission layer EML1 may be any one of a red emission layer emitting red light, a green emission layer emitting green light, a blue emission layer emitting blue light, and a yellow emission layer emitting yellow light, however is not necessarily limited thereto.

The first charge generation layer 342a may be disposed on the first intermediate layer 341a. The first charge generation layer 342a may have a stacked structure in which an N-type charge generation layer NCGL1 for providing electrons to the first intermediate layer 341a and a P-type charge generation layer PCGL1 for providing holes to the second intermediate layer 341b are stacked.

The second intermediate layer 341b may be disposed on the first charge generation layer 342a. The second intermediate layer 341b may have a structure in which a second hole injection layer HTL2, a third hole injection layer HTL3, a second emission layer EML2 which emits light of a second color, and a second electron transport layer ETL2 are sequentially stacked, but is not necessarily limited thereto. The second emission layer EML2 may emit light of a different color than the first emission layer EML1. For example, the first emission layer EML1 may be a red emission layer emitting red light, and the second emission layer EML2 may be a blue emission layer emitting blue light, but are not limited thereto.

The second charge generation layer 342b may be disposed on the second intermediate layer 341b. The second charge generation layer 342b may have a stacked structure in which an N-type charge generation layer NCGL2 for providing electrons to the second intermediate layer 341b and a P-type charge generation layer PCGL2 for providing holes to the third intermediate layer 341c are stacked.

The third intermediate layer 341c may be disposed on the second charge generation layer 342b. The third intermediate layer 341c may have a structure in which a fourth hole transport layer HTL4, a third emission layer EML3 that emits light of a third color, and a third electron transport layer ETL3 are sequentially stacked, but is not necessarily limited thereto. The third emission layer EML3 may be a green emission layer, but is not limited thereto.

The third charge generation layer 342c may be disposed on the third intermediate layer 341c. The third charge generation layer 342c may have a stacked structure in which an N-type charge generation layer NCGL3 for providing electrons to the third intermediate layer 341c and a P-type charge generation layer PCGL3 for providing holes to the fourth intermediate layer 341d are stacked.

The fourth intermediate layer 341d may be disposed on the third charge generation layer 342c. The fourth intermediate layer 341d may have a structure in which a fifth hole transport layer HTL5, a sixth hole transport layer HTL6, a fourth emission layer EML4 that emits light of a fourth color, a fourth electron transport layer ETL4, and an electron injection layer EIL are sequentially stacked, but the structure is not necessarily limited thereto. The fourth emission layer EML4 may be a blue emission layer, but is not limited thereto.

A cathode electrode 350 may be disposed on the fourth intermediate layer 341d.

The cathode electrode 350 may be a reflective electrode which reflects light, and may be made of an opaque conductive material. For example, the cathode electrode 350 may be formed of at least one of silver (Ag), aluminum (Al), gold (Au), molybdenum (Mo), tungsten (W), chromium (Cr), or alloys thereof. but is not limited thereto.

Referring again to FIG. 3, an encapsulation layer 360 may be disposed on the cathode electrode 350.

The encapsulation layer 360 may prevent moisture or oxygen from penetrating into the light emitting device ED. The encapsulation layer 360 may have an organic encapsulation layer and an inorganic encapsulation layer alternately stacked.

The encapsulation layer 360 may include a first encapsulation layer 361, a second encapsulation layer 362, and a third encapsulation layer 363. Here, the first encapsulation layer 361 and the third encapsulation layer 363 may be inorganic encapsulation layers, and the second encapsulation layer 362 may be an organic encapsulation layer, but are not limited thereto.

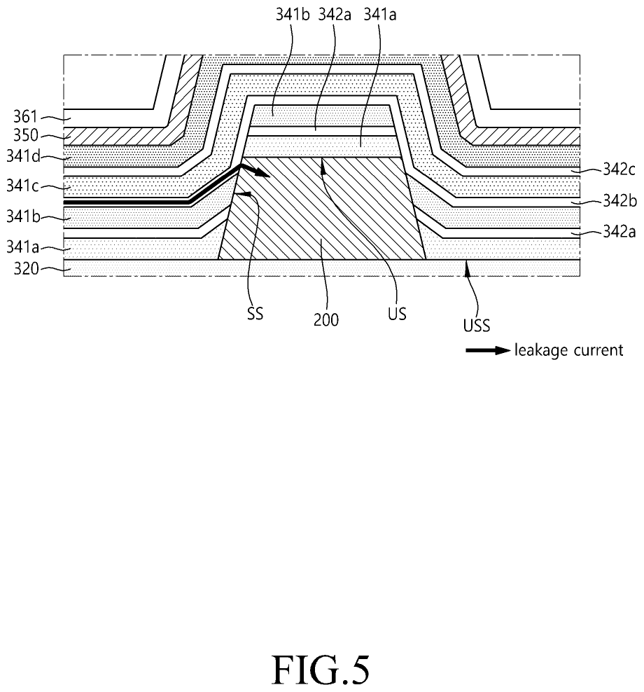

FIG. 5 is an enlarged view of part A of FIG. 3.

Referring to FIG. 5, an organic layer 340 may be disposed on the auxiliary electrode 200. The auxiliary electrode 200 may be located between the organic layer 340 and the overcoat layer 320.

The organic layer 340 may cover a side surface SS and an upper surface US of the auxiliary electrode 200.

The portion of the organic layer 340 located on an upper surface US of the auxiliary electrode 200 may be positioned higher in a vertical direction than a portion of the organic layer 340 located on an upper surface USS of the overcoat layer 320. That is, a vertical distance from the portion of the organic layer 340 located on the upper surface US of the auxiliary electrode 200 to the substrate 300 may be greater than a vertical distance from the portion of the organic layer 340 located on the upper surface USS of the overcoat layer 320 to the substrate 300.

A thickness of the organic layer 340 may be 4700 Å, but is not limited thereto.

At least a portion of the organic layer 340 may be disconnected around the auxiliary electrode 200 due to the auxiliary electrode 200 formed between the organic layer 340 and the overcoat layer 320.

Specifically, as shown in FIG. 5, the first intermediate layer 341a, the first charge generation layer 342a, and the second intermediate layer 341b may be disconnected around the auxiliary electrode 200.

Here, a thickness of the auxiliary electrode 200 may be 800 Å or less as described above, but is not limited thereto.

A portion of the first intermediate layer 341a, the first charge generation layer 342a, and the second intermediate layer 341b may be in contact with both side surfaces SS of the auxiliary electrode 200.

Other portions of the first intermediate layer 341a, the first charge generation layer 342a, and the second intermediate layer 341b may be located on the auxiliary electrode 200.

Among the portions of the first intermediate layer 341a, the first charge generation layer 342a, and the second intermediate layer 341b, the portion contacting both side surfaces SS of the auxiliary electrode 200 and the portion located on the auxiliary electrode 200 may not be connected to each other.

At least a portion of the second charge generation layer 342b may be in contact with the side surface SS of the auxiliary electrode 200.

As described above, the second charge generation layer 342b may include an N-type charge generation layer NCGL2 and a P-type charge generation layer PCGL2 on the N-type charge generation layer NCGL2.

The N-type charge generation layer NCGL2 may contact at least a portion of the side surface SS of the auxiliary electrode 200.

Since the N-type charge generation layer NCGL2 contacts at least a portion of the side surface SS of the auxiliary electrode 200, at least a portion of the current flowing along the N-type charge generation layer NCGL2 may flow to the auxiliary electrode 200, as shown in FIG. 5.

The current flowing along the N-type charge generation layer NCGL2 may be a current leaked from one subpixel adjacent to the auxiliary electrode 200.

Since the current leaked from one adjacent subpixel may pass through the side of the auxiliary electrode 200 and flow to the auxiliary electrode 200, the current may not flow to another subpixel adjacent to the auxiliary electrode 200 in a direction different from that of one adjacent subpixel.

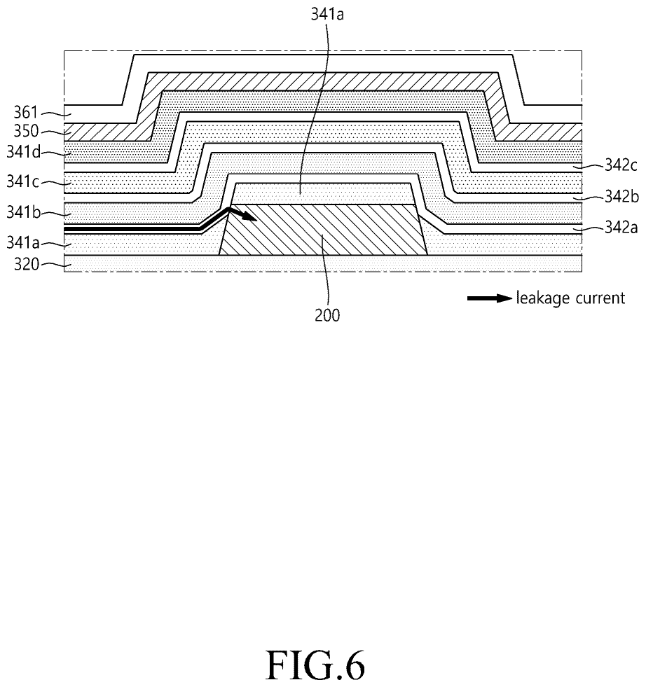

FIG. 6 illustrates another example of the cross-sectional structure shown in FIG. 5.

In describing this embodiment, it will be omitted the description of components that are substantially the same as or corresponding to the previous embodiment.

A thickness of the auxiliary electrode 200 shown in FIG. 6 may be smaller than a thickness of the auxiliary electrode 200 described with reference to FIGS. 3 and 5.

If the thickness of the auxiliary electrode 200 is reduced, there may be reduced the number of layers disconnected by the auxiliary electrode 200 among the organic layers 340.

Specifically, as shown in FIG. 6, the first intermediate layer 341a may be disconnected around the auxiliary electrode 200.

A portion of the first intermediate layer 341a may contact both side surfaces SS of the auxiliary electrode 200.

Another portion of the first intermediate layer 341a may be located on the auxiliary electrode 200.

The portion of the first intermediate layer 341a contacting both side surfaces SS of the auxiliary electrode 200 and the portion of the first intermediate layer 341a located on the auxiliary electrode 200 may not be connected to each other.

At least a portion of the first charge generation layer 342a may be in contact with the side surface SS of the auxiliary electrode 200.

As described above, the first charge generation layer 342a may include an N-type charge generation layer NCGL1 and a P-type charge generation layer PCGL1 on the N-type charge generation layer NCGL1.

The N-type charge generation layer NCGL1 may contact at least a portion of the side surface SS of the auxiliary electrode 200.

Since the N-type charge generation layer NCGL1 contacts at least a portion of the side surface SS of the auxiliary electrode 200, as shown in FIG. 6, at least a portion of the current flowing along the N-type charge generation layer NCGL1 may flow into the auxiliary electrode 200.

The current flowing along the N-type charge generation layer NCGL1 may be a current leaked from one subpixel adjacent to the auxiliary electrode 200.

Referring to FIGS. 5 and 6, the leakage current flowing along the first charge generation layer 342a and the second charge generation layer 342b may be a current in which some of the current flowing in the subpixel leaks when supplying the data voltage to the subpixel for driving the subpixel.

Here, current leaked from one subpixel may flow to another adjacent subpixel through the organic layer 340.

In this case, since the charge generation layers 342a, 342b, and 342c of the organic layer 340 have low resistance, most of the leaked current may flow along the charge generation layers 342a, 342b, and 342c.

Since the leaked current may reach another adjacent subpixel through the charge generation layers 342a, 342b, and 342c, a light emitting device included in another adjacent subpixel may be driven even when the data voltage is not supplied to the other adjacent subpixel.

Therefore, light may be emitted from other adjacent subpixels which are not required to emit light, which may cause a problem in that it becomes difficult to independently control the emitted light of each subpixel.

In addition, as light is emitted from other adjacent subpixels which are not required to emit light, a problem may occur in which the color of the emitted subpixel is not properly implemented. That is, there may be deteriorated the color gamut characteristics in low gray levels of subpixels.

However, as shown in FIGS. 5 and 6, if the first charge generation layer 342a or the second charge generation layer 342b contacts the side surface SS of the auxiliary electrode 200, at least a portion of the leakage current flowing along the first charge generation layer 342a or the second charge generation layer 342b may flow through the auxiliary electrode 200. Here, the auxiliary electrode 200 may be connected to a cathode electrode supplied with a base voltage, as will be described later, so the leakage current may not flow to other adjacent subpixels and may be removed in the middle through the auxiliary electrode 200.

Therefore, the leakage current flowing between adjacent subpixels may be blocked, so that there may become easier to independently control the light output of each subpixel.

In addition, a subpixel which does not want to emit light may be blocked from emitting light due to current leaked from an adjacent subpixel emitting light, thereby improving the color gamut of the subpixels in low gray levels.

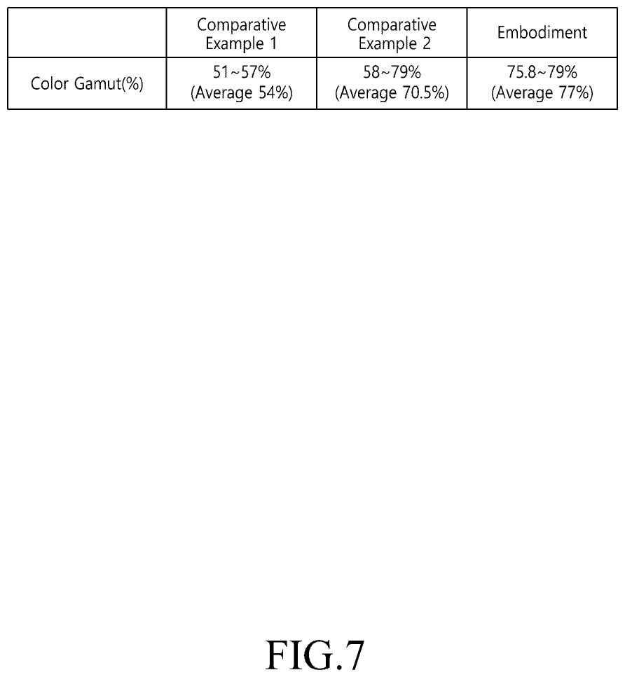

FIG. 7 is a table illustrating the color gamut of a display device according to embodiments of the present disclosure.

Referring to FIG. 7, a comparative example 1 is data expressing the color gamut in numbers when the organic layer 340 is not disconnected by the auxiliary electrode 200. The comparative example 2 is data expressing the color gamut in numbers when both the first charge generation layer 342a and the second charge generation layer 342b of the organic layer 340 are disconnected by the auxiliary electrode 200. The embodiment is data expressing the color gamut when the first charge generation layer 342a of the organic layer 340 is disconnected by the auxiliary electrode 200 and at least a portion of the second charge generation layer 342b is in contact with the side surface SS of the auxiliary electrode 200.

In order to prevent the entire organic layer 340 including the first charge generation layer 342a and the second charge generation layer 342b from being disconnected, a thickness of the auxiliary electrode 200 in the case of the comparative example 1 may be smaller than a thickness of the auxiliary electrode 200 in the comparative example 2 and the embodiment.

Since the organic layer 340 is not disconnected, current leaked from one subpixel may flow to another adjacent subpixel through the first charge generation layer 342a and the second charge generation layer 342b. In this case, subpixels may have a color gamut value of 51 to 57% (average 54%). Here, as each subpixel fully expresses its color without being interfered with by other subpixels, the color gamut (%) has a higher value.

That is, in the case of the comparative example 1, all leakage current may flow to other adjacent subpixels, so the color gamut characteristics of other adjacent subpixels may be low.

In order to enable both the first charge generation layer 342a and the second charge generation layer 342b of the organic layer 340 to be disconnected, a thickness of the auxiliary electrode 200 in the case of the comparative example 2 may be greater than a thickness of the auxiliary electrode 200 in the comparative example 1 and the embodiment.

Therefore, current leaked from one subpixel cannot flow to another adjacent subpixel through the first charge generation layer 342a and the second charge generation layer 342b. In this case, the subpixels may have a relatively high color gamut value of 58 to 79% (average 70.5%) compared to the comparative example 1.

However, in the case of the comparative example 2, the thickness of the auxiliary electrode 200 is required to be very large in order to disconnect both the first charge generation layer 342a and the second charge generation layer 342b. For example, the thickness of the auxiliary electrode 200 may be 1250 Å or more.

If the thickness of the auxiliary electrode 200 is greater than 1250 Å, not only the organic layer 340 but also the cathode electrode may be disconnected. If the cathode electrode is disconnected, various types of moisture or oxygen may penetrate through a gap created at a point where the cathode electrode is disconnected. Accordingly, there may be occurred a subpixel driving failure.

In the case of the embodiment, in order for the first charge generation layer 342a to be disconnected and at least a portion of the second charge generation layer 342b to contact the side surface SS of the auxiliary electrode 200, the thickness of the auxiliary electrode 200 may be larger than that in the comparative example 1, and smaller than that in the comparative example 2. For example, the thickness of the auxiliary electrode 200 may be 800 Å or less as described above.

If the auxiliary electrode 200 has the thickness as above, the first charge generation layer 342a may be disconnected, and at least a portion of the second charge generation layer 342b may contact the side surface SS of the auxiliary electrode 200.

As described above, current leaked from one subpixel may flow to the auxiliary electrode 200 through the side surface SS of the auxiliary electrode 200, so the leakage current may be removed through the auxiliary electrode 200, and may not flow to other adjacent subpixels. In this case, the subpixels may have a color gamut value of 75.8% to 79% (average 77%).

In addition, if the auxiliary electrode 200 has the above-mentioned thickness, the problem of disconnection of the cathode electrode may not occur, and thus there may be prevented a driving failure due to moisture or oxygen penetration.

Hereinafter, it will be described another structure of the auxiliary electrode 200 capable of blocking the leakage current.

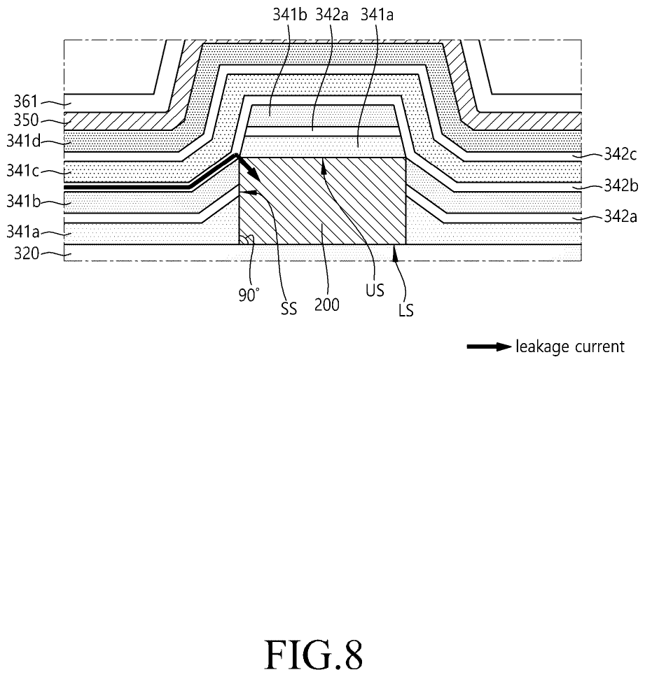

FIG. 8 illustrates another example of the cross-sectional structure shown in FIG. 5.

In describing this embodiment, it will be omitted the description of components that are substantially the same as or corresponding to the previous embodiment.

Referring to FIG. 8, the auxiliary electrode 200 may be disposed on the overcoat layer 320 in the non-emission area NEA.

A size of the upper surface US of the auxiliary electrode 200 may be the same as a size of the lower surface LS. Alternatively, an angle formed by the side surface SS of the auxiliary electrode 200 and the substrate 300 may be 90 degrees.

The thickness of the auxiliary electrode 200 may be 800 Å or less, but is not limited thereto.

As shown in FIG. 8, the first intermediate layer 341a, the first charge generation layer 342a, and the second intermediate layer 341b may be disconnected around the auxiliary electrode 200.

A portion of the first intermediate layer 341a, the first charge generation layer 342a, and the second intermediate layer 341b may contact both side surfaces of the auxiliary electrode 200.

Other portions of the first intermediate layer 341a, the first charge generation layer 342a, and the second intermediate layer 341b may be located on the auxiliary electrode 200.

In the first intermediate layer 341a, the first charge generation layer 342a, and the second intermediate layer 341b, a portion contacting both side surfaces of the auxiliary electrode 200 and a portion located on the auxiliary electrode 200 may not be connected to each other.

The second charge generation layer 342b may be in contact with a line where an upper surface and a side surface of the auxiliary electrode 200 meet.

As described above, the second charge generation layer 342b may include an N-type charge generation layer NCGL2 and a P-type charge generation layer PCGL2 on the N-type charge generation layer NCGL2.

The N-type charge generation layer NCGL2 may be in contact with a line where the upper surface and the side surface of the auxiliary electrode 200 meet.

As the N-type charge generation layer NCGL2 contacts the line where the upper surface and the side surface of the auxiliary electrode 200 meet, at least a portion of the current flowing along the N-type charge generation layer NCGL2 may flow to the auxiliary electrode 200, as shown in FIG. 8.

In FIG. 8, there is illustrated a case in which the second charge generation layer 342b is in contact with the line where the upper surface and the side surface of the auxiliary electrode 200 meet as an example, but the case is not limited thereto, and the first charge generation layer 342a may be in contact with the line where the upper and side surfaces of the auxiliary electrode 200 meet.

That is, the current leaking from one subpixel and flowing along the first charge generation layer 342a or the second charge generation layer 342b may flow to the auxiliary electrode 200 through a point where the first charge generation layer 342a or the second charge generation layer 342b contacts the upper surface and the side surface of the auxiliary electrode 200. In this case, the current flowing to the auxiliary electrode 200 may flow to the cathode electrode supplied with the base voltage, as will be described later, so the leakage current cannot flow to the adjacent subpixel and can be removed in the middle through the auxiliary electrode 200.

Therefore, there may block the leakage current flowing between adjacent subpixels, thereby making it easier to independently control the light output of each subpixel.

In addition, subpixels that do not want to emit light may be blocked from being driven by current leaked from adjacent subpixels emitting light, thereby improving the color gamut of subpixels in low gray levels.

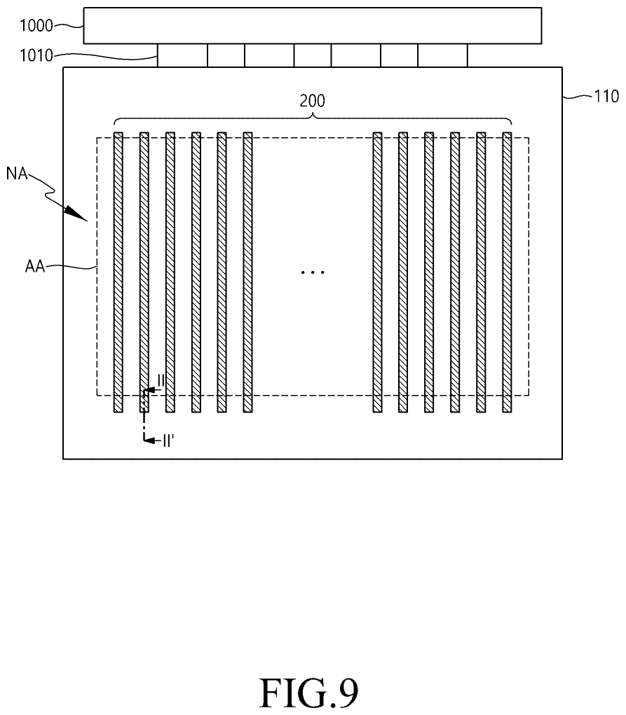

FIG. 9 illustrates an example of a planar structure of a display panel according to embodiments of the present disclosure.

Referring to FIG. 9, the display panel 110 may be connected to a data driver 1000. The data driver 1000 may be a circuit for driving a plurality of data lines, and may output data signals through the plurality of data lines.

The data driver 1000 may receive digital image data DATA from a timing controller, convert the received image data DATA into an analog data signal, and output to a plurality of data lines.

In FIG. 9, it is illustrated a case in which the data driver 1000 is connected to the display panel 110 through the film 1010 in a chip-on-film (COF) method, but is not limited thereto, and the data driver 1000 may be connected to the display panel 110 using a tape automated bonding (TAB) method, or may be connected to a bonding pad of the display panel 110 using a chip-on-glass (COG) or a chip-on-panel (COP) method.

A plurality of auxiliary electrodes 200 may be disposed to at least partially overlap a display area AA of the display panel 110.

The display area AA may refer to an area where a plurality of subpixels SP are disposed.

The auxiliary electrodes 200 may be disposed between the plurality of subpixels SP within the display area AA.

The auxiliary electrodes 200 may overlap a data line or a reference voltage line, but are not limited thereto.

The non-display area NA may surround the display area AA outside the display area AA.

Some of the auxiliary electrodes 200 may be disposed in the non-display area NA. However, the present disclosure is not limited thereto, and the auxiliary electrodes 200 may be disposed only within the display area AA.

The auxiliary electrodes 200 may be electrically connected to the cathode electrode in the non-display area NA.

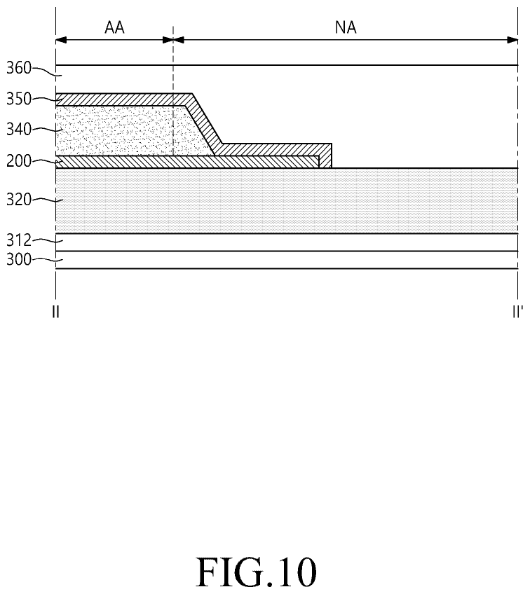

FIG. 10 illustrates an example of the cross-sectional structure of portion II-II′ of FIG. 9.

Referring to FIG. 10, a buffer layer 312 may be disposed on the substrate 300, an overcoat layer 320 may be disposed on the buffer layer 312, and the auxiliary electrode 200 may be disposed on the overcoat layer 320.

An organic layer 340 and a cathode electrode 350 may be disposed on the auxiliary electrode 200.

The organic layer 340 may be disposed on the auxiliary electrode 200 in the display area AA.

The organic layer 340 may include a plurality of intermediate layers 341 and a plurality of charge generation layers 342, as described above.

The organic layer 340 may be partially disposed in the non-display area NA.

The cathode electrode 350 may be disposed on the organic layer 340.

In the display area AA, the cathode electrode 350 may be separated from the auxiliary electrode 200. The organic layer 340 may be disposed between the cathode electrode 350 and the auxiliary electrode 200 in the display area AA.

In at least a portion of the non-display area NA, the cathode electrode 350 may be electrically connected to the auxiliary electrode 200.

In at least a portion of the non-display area NA, an upper surface of the auxiliary electrode 200 may contact a lower surface of the cathode electrode 350.

However, the present disclosure is not limited thereto, and the cathode electrode 350 may be electrically connected to the auxiliary electrode 200 in the display area AA.

A base voltage may be supplied to the cathode electrode 350. Since the cathode electrode 350 is electrically connected to the auxiliary electrode 200, the auxiliary electrode 200 may be supplied with the base voltage. That is, leakage current generated in at least one subpixel may be removed by the auxiliary electrode 200 disposed adjacent to the subpixel.

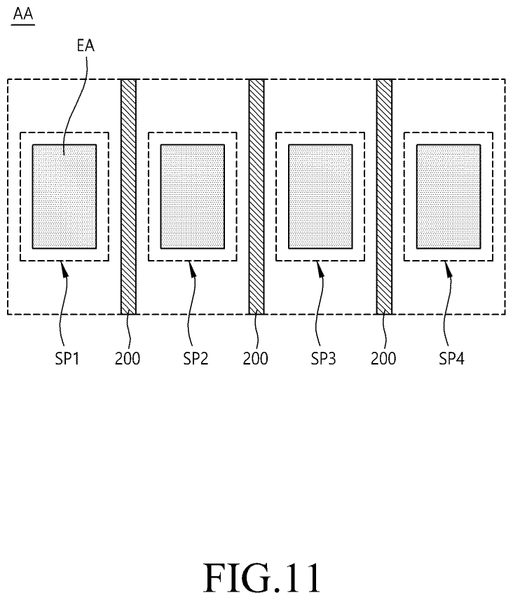

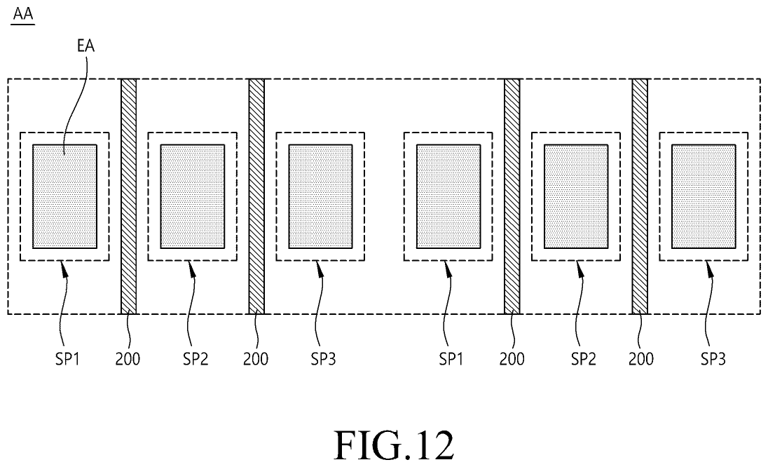

FIGS. 11 and 12 illustrate another example of a planar structure of a subpixel.

Referring to FIG. 11, a number of subpixels SP may be disposed in the display area AA.

The plurality of subpixels SP may include a white subpixel, a red subpixel, a green subpixel, and a blue subpixel.

Here, a first subpixel SP1 may be a red subpixel, a second subpixel SP2 may be a white subpixel, a third subpixel SP3 may be a blue subpixel, and a fourth subpixel SP4 may be a green subpixel.

An auxiliary electrode 200 may be disposed between each subpixel SP1, SP2, SP3 and SP4.

The side surface of the auxiliary electrode 200 may contact at least a portion of a first charge generation layer 342a or a second charge generation layer 342b, as described with reference to FIGS. 5 to 8.

In addition, the auxiliary electrode 200 may be connected to the cathode electrode.

If the auxiliary electrode 200 is disposed between each of the subpixels as shown in FIG. 11, the leakage current that may occur between adjacent subpixels can be removed through the auxiliary electrode 200.

Therefore, the light emission of subpixels may be controlled independently, and the color gamut of subpixels may be improved.

Referring to FIG. 12, a plurality of subpixels SP may include a red subpixel, a green subpixel, and a blue subpixel, respectively.

Here, a first subpixel SP1 may be a red subpixel, a second subpixel SP2 may be a green subpixel, and a third subpixel SP3 may be a blue subpixel.

The auxiliary electrode 200 may be disposed on both sides of the second subpixel SP2. That is, the auxiliary electrode 200 may be disposed between the emission area EA of the second subpixel SP2 and the emission area EA of the first subpixel SP1 and between the emission area EA of the second subpixel SP2 and the emission areas EA of the third subpixel SP3.

The auxiliary electrode 200 may not be disposed between the emission area EA of the first subpixel SP1 and the emission area EA of the third subpixel SP3.

The side surface of the auxiliary electrode 200 may be in contact with at least a portion of the first charge generation layer 342a or the second charge generation layer 342b, as described with reference to FIGS. 5 to 8, and the auxiliary electrode 200 may be connected to the cathode electrode.

Since the auxiliary electrode 200 is disposed between the first subpixel SP1 and the second subpixel SP2 and between the third subpixel SP3 and the second subpixel SP2, the current leaked from the first subpixel SP1 or the third subpixel SP3 and flowing into the second subpixel SP2 may be removed through the auxiliary electrode 200.

In the case that the second subpixel SP2 is a green subpixel, since the color filter transmittance of green light is higher than the color filter transmittance of light of other colors, even if the same current flows, the amount of light emitted from the green subpixel and passing through the color filter may be greater. That is, even if the same amount of current flows through each subpixel, the amount of light emitted from the green subpixel may be greater.

Therefore, if the auxiliary electrode 200 is disposed around the second subpixel SP2, it is possible to improve the problem of lowering the color gamut of the subpixels due to the emission of the undesired subpixels by the leakage current.

In addition, the auxiliary electrode 200 may be selectively disposed only around the second subpixel SP2, so that it is possible to prevent a decrease in the aperture ratio of the display area AA where the subpixels SP2 are disposed.

The embodiments of the present disclosure described above are briefly described as follows.

According to an embodiment of the present disclosure, there may provide a display device including a substrate including a plurality of subpixels, each of the plurality of subpixels including an emission area, an overcoat layer on the substrate, an auxiliary electrode disposed between the emission areas of adjacent subpixels among the plurality of subpixels and disposed on the overcoat layer, and an organic layer disposed on the overcoat layer and the auxiliary electrode, including at least one charge generation layer, and at least a portion of the at least one charge generation layer contacting the auxiliary electrode.

In the display device according to an embodiment of the present disclosure, at least a portion of the at least one charge generation layer may be in contact with a line where an upper surface and a side surface of the auxiliary electrode meet.

In the display device according to an embodiment of the present disclosure, at least a portion of the at least one charge generation layer may be in contact with a side surface of the auxiliary electrode.

In the display device according to an embodiment of the present disclosure, a distance from a portion of the organic layer located on an upper surface of the auxiliary electrode to the substrate may be greater than a distance from a portion of the organic layer located on an upper surface of the overcoat layer to the substrate.

In the display device according to an embodiment of the present disclosure, the organic layer may further include at least one intermediate layer, and at least one intermediate layer may be disconnected around the auxiliary electrode.

In the display device according to an embodiment of the present disclosure, the at least one intermediate layer may be in contact with a side surface of the auxiliary electrode.

In the display device according to an embodiment of the present disclosure, the organic layer may include a first charge generation layer and a second charge generation layer located on the first charge generation layer, and at least a portion of the first charge generation layer may be in contact with the auxiliary electrode.

In the display device according to an embodiment of the present disclosure, the organic layer may include a first charge generation layer and a second charge generation layer located on the first charge generation layer, and at least a portion of the second charge generation layer is in contact with the auxiliary electrode.

In the display device according to an embodiment of the present disclosure, the first charge generation layer may be disconnected around the auxiliary electrode.

In the display device according to an embodiment of the present disclosure, the substrate may include a display area where the plurality of subpixels are disposed and a non-display area around the display area. The display device may further include a cathode electrode disposed separately from the auxiliary electrode in the display area and electrically connected to at least a portion of the auxiliary electrode in the non-display area.

In the display device according to an embodiment of the present disclosure, the plurality of subpixels may include a white subpixel, a red subpixel, a blue subpixel, and a green subpixel, and the auxiliary electrode may be disposed between emission areas of adjacent subpixels among the plurality of subpixels.

In the display device according to an embodiment of the present disclosure, the plurality of subpixels may include a white subpixel, a red subpixel, a blue subpixel, and a green subpixel, and the auxiliary electrode may be disposed between an emission area of the green subpixel and an emission area of the red subpixel, and/or between an emission area of the green subpixel and an emission area the blue subpixel.

In the display device according to an embodiment of the present disclosure, each of the plurality of subpixels may include an anode electrode, and a thickness of the auxiliary electrode may be different from a thickness of the anode electrode.

According to an embodiment of the present disclosure, there may provide a display device including a substrate including a plurality of subpixels, each of the plurality of subpixels including an emission area, an overcoat layer on the substrate, an auxiliary electrode disposed between emission areas of adjacent subpixels among the plurality of subpixels and disposed on the overcoat layer, and an organic layer disposed on the overcoat layer and the auxiliary electrode, at least a portion of the organic layer contacting a side surface of the auxiliary electrode.

In the display device according to an embodiment of the present disclosure, the organic layer may include a first charge generation layer and a second charge generation layer located on the first charge generation layer, and at least a portion of the first charge generation layer may be in contact with the auxiliary electrode.

In the display device according to an embodiment of the present disclosure, the organic layer may include a first charge generation layer and a second charge generation layer located on the first charge generation layer, and at least a portion of the second charge generation layer may be in contact with the auxiliary electrode.

In the display device according to an embodiment of the present disclosure, the substrate may include a display area where the plurality of subpixels are disposed and a non-display area around the display area. The display device may further include a cathode electrode disposed separately from the auxiliary electrode in the display area and electrically connected to at least a portion of the auxiliary electrode in the non-display area.

In the display device according to an embodiment of the present disclosure, the plurality of subpixels may include a white subpixel, a red subpixel, a blue subpixel, and a green subpixel, and the auxiliary electrode may be disposed between emission areas of adjacent subpixels among the plurality of subpixels.

In the display device according to an embodiment of the present disclosure, the plurality of subpixels may include a white subpixel, a red subpixel, a blue subpixel, and a green subpixel, and the auxiliary electrode may be disposed between an emission area of the green subpixel and an emission area of the red subpixel, and/or between an emission area of the green subpixel and an emission area the blue subpixel.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a plurality of subpixels, each of the plurality of subpixels including an emission area;
an overcoat layer on the substrate;
an auxiliary electrode disposed between the emission areas of adjacent subpixels among the plurality of subpixels, the auxiliary electrode on the overcoat layer; and
an organic layer on the overcoat layer and the auxiliary electrode, the organic layer including at least one charge generation layer, and
wherein at least a portion of the at least one charge generation layer contacts the auxiliary electrode.

2. The display device of claim 1, wherein at least a portion of the at least one charge generation layer is in contact with a line where an upper surface and a side surface of the auxiliary electrode meet.

3. The display device of claim 1, wherein at least a portion of the at least one charge generation layer is in contact with a side surface of the auxiliary electrode.

4. The display device of claim 1, wherein a distance from a portion of the organic layer located on an upper surface of the auxiliary electrode to the substrate is greater than a distance from a portion of the organic layer located on an upper surface of the overcoat layer to the substrate.

5. The display device of claim 1, wherein the organic layer further includes at least one intermediate layer,
wherein the at least one intermediate layer is disconnected around the auxiliary electrode.

6. The display device of claim 5, wherein the at least one intermediate layer is in contact with a side surface of the auxiliary electrode.

7. The display device of claim 1, wherein the organic layer includes a first charge generation layer and a second charge generation layer on the first charge generation layer,
wherein at least a portion of the first charge generation layer is in contact with the auxiliary electrode.

8. The display device of claim 1, wherein the organic layer includes a first charge generation layer and a second charge generation layer on the first charge generation layer,
wherein at least a portion of the second charge generation layer is in contact with the auxiliary electrode.

9. The display device of claim 8, wherein the first charge generation layer is disconnected around the auxiliary electrode.

10. The display device of claim 1, wherein the substrate includes a display area where the plurality of subpixels is disposed and a non-display area around the display area,
wherein the display device further includes a cathode electrode disposed separately from the auxiliary electrode in the display area and electrically connected to at least a portion of the auxiliary electrode in the non-display area.

11. The display device of claim 1, wherein the plurality of subpixels includes a white subpixel, a red subpixel, a blue subpixel, and a green subpixel,
wherein the auxiliary electrode is disposed between emission areas of adjacent subpixels among the plurality of subpixels.

12. The display device of claim 1, wherein the plurality of subpixels includes a red subpixel, a blue subpixel, and a green subpixel,
wherein the auxiliary electrode is disposed between an emission area of the green subpixel and an emission area of the red subpixel, and/or between an emission area of the green subpixel and an emission area the blue subpixel.

13. The display device of claim 1, wherein each of the plurality of subpixels includes an anode electrode,
wherein a thickness of the auxiliary electrode is different from a thickness of the anode electrode.

14. A display device comprising:
a substrate including a plurality of subpixels, each of the plurality of subpixels including an emission area;
an overcoat layer on the substrate;
an auxiliary electrode disposed between emission areas of adjacent subpixels among the plurality of subpixels, the auxiliary electrode on the overcoat layer; and
an organic layer on the overcoat layer and the auxiliary electrode, at least a portion of the organic layer contacting a side surface of the auxiliary electrode.

15. The display device of claim 14, wherein the organic layer includes a first charge generation layer and a second charge generation layer on the first charge generation layer,
wherein at least a portion of the first charge generation layer is in contact with the auxiliary electrode.

16. The display device of claim 14, wherein the organic layer includes a first charge generation layer and a second charge generation layer on the first charge generation layer,
wherein at least a portion of the second charge generation layer is in contact with the auxiliary electrode.

17. The display device of claim 14, wherein the substrate includes a display area where the plurality of subpixels is disposed and a non-display area around the display area,
wherein the substrate further includes a cathode electrode disposed separately from the auxiliary electrode in the display area and electrically connected to at least a portion of the auxiliary electrode in the non-display area.

18. The display device of claim 14, wherein the plurality of subpixels includes a white subpixel, a red subpixel, a blue subpixel, and a green subpixel, and
wherein the auxiliary electrode is disposed between emission areas of adjacent subpixels among the plurality of subpixels.

19. The display device of claim 14, wherein the plurality of subpixels includes a red subpixel, a blue subpixel, and a green subpixel,
wherein the auxiliary electrode is disposed between an emission area of the green subpixel and an emission area of the red subpixel, and/or between an emission area of the green subpixel and an emission area the blue subpixel.
